(19) United States
(12) Patent Application Publication
(10) Pub. No.: US 2019/0067477 A1
(43) Pub. Date: Feb. 28, 2019

(54) SEMICONDUCTOR STRUCTURE WITH DOPED FIN-SHAPED STRUCTURES AND METHOD OF FABRICATING THE SAME

(71) Applicant: UNITED MICROELECTRONICS CORP., Hsin-Chu City (TW)

(72) Inventors: Shi-You Liu, Kaohsiung City (TW); Ming-Shiou Hsieh, Chiayi County (TW); Rong-Sin Lin, Taichung City (TW); Han-Ting Yen, Yunlin County (TW); Tsai-Yu Wen, Tainan City (TW); Ching-I Li, Tainan City (TW)

(21) Appl. No.: 15/688,824

(22) Filed: Aug. 28, 2017

(51) Int. Cl. H01L 29/78; H01L 21/8234; H01L 27/088; H01L 29/06

(52) U.S. Cl. CPC H01L 29/7846; H01L 21/823431; H01L 29/0653; H01L 27/0886; H01L 21/823481

(57) ABSTRACT

A semiconductor structure includes a substrate, fin-shaped structures disposed on the substrate, an isolation layer disposed between the fin-shaped structures, and a doped region disposed in an upper portion of the isolation layer, where the doped region is doped with helium or neon.

### BACKGROUND OF THE INVENTION

### 1. Field of the Invention

The present invention relates generally to the field of semiconductor structure with fin-shaped structures, and more particularly to a semiconductor structure with periodically arranged fin-shaped structures and the method of fabricating the same.

### 2. Description of the Prior Art

Semiconductor devices are used in a large number of electronic devices, such as computer, communication, consumer electronics, cars and others. Semiconductor devices comprise integrated circuits (ICs) that are formed on semiconductor wafers by depositing many types of thin films of material over the semiconductor wafers, and patterning the thin films of material to form the integrated circuits. The most common active element in the ICs is transistor including planar field-effect transistors (FETs) such as metal oxide semiconductor (MOS) transistors and 3D fin field-effect transistors (FinFETs).

In generally, a fin field-effect transistor may include periodically arranged fin-shaped structures which are often physically and electrically separated by a trench isolation structure, such as shallow trench isolation (STI). The fin-shaped structures protruding from the STI may act as active regions of the transistors. Since the height to width ratio of each fin-shaped structure is gradually increased with the advance of the semiconductor techniques, several drawbacks, such as fin bending or cracking, often occurs when the process of fabricating STI is completed and thus degrade the performance of the corresponding fin field-effect transistor.

### SUMMARY OF THE INVENTION

In order to overcome the drawbacks disclosed above, there is a need for providing an improved fin field-effect transistor and the method of fabricating the same.

According to one embodiment of the present invention, a semiconductor structure is provided and includes a substrate, fin-shaped structures disposed on the substrate, an isolation layer disposed between the fin-shaped structures, and a doped region disposed in an upper portion of the isolation layer, where the doped region is doped with helium or neon.

According to another embodiment of the present invention, a method for fabricating a semiconductor structure is provided and includes the following steps: providing a substrate; forming fin-shaped structures on the substrate; forming an isolation layer to fill up a space between the fin-shaped structures; performing a first ion implantation process to implant an element to the isolation layer, where the first ion implantation process has a first ion implantation energy; performing a second ion implantation process to implant another element to the isolation layer, where the second ion implantation process has a second ion implantation energy different from the first ion implantation energy; and annealing the isolation layer after performing the first and the second ion implantation processes.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-9 are schematic cross-sectional diagrams showing a method for fabricating a semiconductor structure according to one embodiment of the present invention.

FIG. 10 is a flow chart showing a method for fabricating a semiconductor structure according to one embodiment of the present invention.

### DETAILED DESCRIPTION

The invention will be described more fully hereinafter with reference to the accompanying drawings, in which example embodiments of the invention are shown. This invention may, however, be embodied in many different forms and should not be construed as limited to the example embodiments set forth herein. Rather, the disclosed embodiments are provided so that this disclosure will be thorough and complete, and will fully convey the scope of the invention to those skilled in the art. In the drawings, the size and relative sizes of layers and regions may be exaggerated for clarity unless express so defined herein. Moreover, each embodiment described and illustrated herein includes its complementary conductivity type embodiment as well. Like numbers refer to like elements throughout.

It will be understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first,” “second,” and other numerical terms when used herein do not imply a sequence or order unless clearly indicated by the context. Thus, a first element, component, region, layer and/or section discussed below could be termed a second element, component, region, layer and/or section without departing from the teachings of the embodiments.

Spatially relative terms, such as “inner,” “outer,” “beneath,” “below,” “lower,” “above,” “upper” and the like, may be used herein for ease of description to describe one element and/or feature's relationship to another element(s) and/or feature(s) as illustrated in the figures. Spatially relative terms may be intended to encompass different orientations of the device in use or operation in addition to the orientation depicted in the figures. For example, if the device in the figures is turned over, elements described as “below” and/or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting. As used herein, the singular terms “a”, “an,” and “the” may be intended to include the plural forms as well, unless the context clearly indicates otherwise. The terms “comprises,” “comprising,” “includes” and/or “including” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

Example embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, may be expected. Thus, the disclosed example embodiments of the invention should not be construed as limited to the particular shapes of regions illustrated herein unless expressly so defined herein, but are to include deviations in shapes that result, for example, from manufacturing. Thus, the regions illustrated in the figures are schematic in nature and their shapes are not intended to illustrate the actual shape of a region of a device and are not intended to limit the scope of the invention, unless expressly so defined herein.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In the following paragraphs, processes for fabricating a semiconductor structure with fin-shaped structures are described in detail.

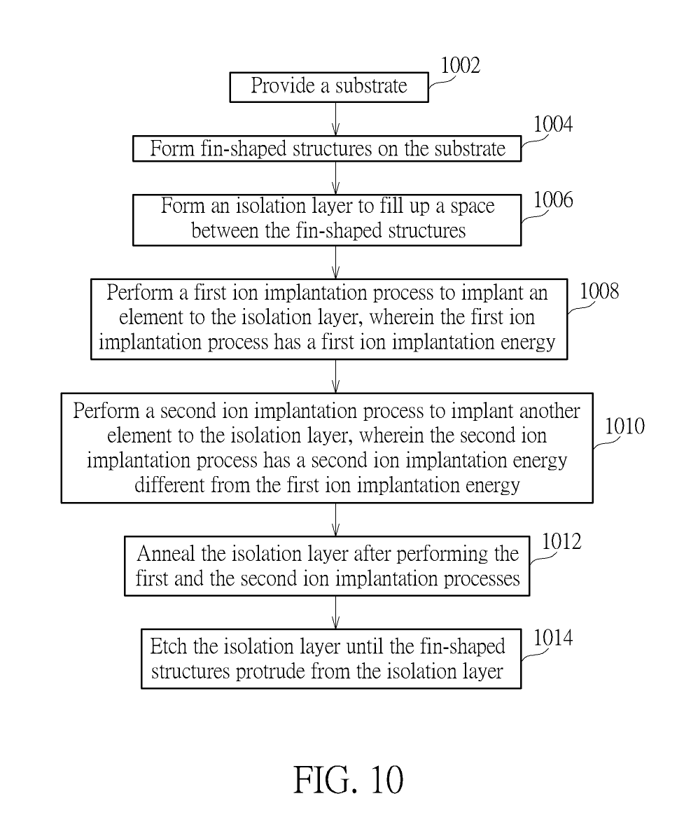

Referring to FIG. 1 and FIG. 10, in step 1002, a substrate 100 is provided. The substrate 100 may be a bulk silicon substrate. Alternatively, the substrate 100 may comprise an elementary semiconductor, such as silicon (Si) or germanium (Ge) in a crystalline structure; a compound semiconductor, such as silicon germanium (SiGe), silicon carbide (SiC), gallium arsenic (GaAs), gallium phosphide (GaP), indium phosphide (InP), indium arsenide (InAs), and/or indium antimonide (InSb); or a combination thereof. Further, the substrates 100 may also include a silicon-on-insulator (SOI) substrate. Generally, an SOI substrate comprises a layer of a semiconductor material such as silicon (Si), germanium (Ge), silicon germanium (SiGe), silicon germanium on insulator (SGOI), or a combination thereof. The SOI substrate 100 is fabricated using separation by implantation of oxygen (SIMOX), wafer bonding, and/or other suitable methods. Other substrates that may be used include multi-layered substrates, gradient substrates, or hybrid orientation substrates. In the embodiment, the substrate 100 is a bulk silicon substrate. That is to say, a fin structure, which will be discussed latter, is physically connected to the substrate 100.

Then, in step 1004, several fin-shaped structures 110 and trenches 102 are fabricated by etching the substrate 100. In particularly, in order to form the trench 102 and the fin-shaped structure 110, a hard mask 130 is formed first and followed by an etching process to remove a portion of the substrate 100 not covered and protected by the hard mask 130, thus the fin-shaped structure 110 is formed between the two adjacent trenches 102. The hard mask 130 may be fabricated by depositing a hard mask layer (not shown) through a suitable process such as, but not limited to, chemical vapor deposition (CVD), plasma enhanced chemical vapor deposition (PECVD), low pressure chemical vapor deposition (LPCVD), or even silicon oxide formation followed by nitridation, may alternatively be utilized. In addition, the hard mask layer (not shown) may be any suitable material such as titanium oxide (TiO₂), tantalum oxide (TaO), silicon nitride (SiN), silicon oxide (SiO₂), silicon carbide (SiC), silicon carbide nitride (SiCN), and a combination thereof. Once the hard mask layer (not shown) is formed, the hard mask layer is patterned through a suitable photolithographic and etching process to form a pattern. A portion of the hard mask layer over the substrate may act as the hard mask 130 used to define the position of the fin-shaped structure 110, while other portions of the hard mask layer over the substrate 100 may be removed so as to define the position of the trench 102. After the formation of the hard mask 130, an etching process is performed to etch the substrate 100 not covered and protected by the hard mask 130. Therefore, the fin-shaped structure 110 is formed between the hard mask 130 and the substrate 100.

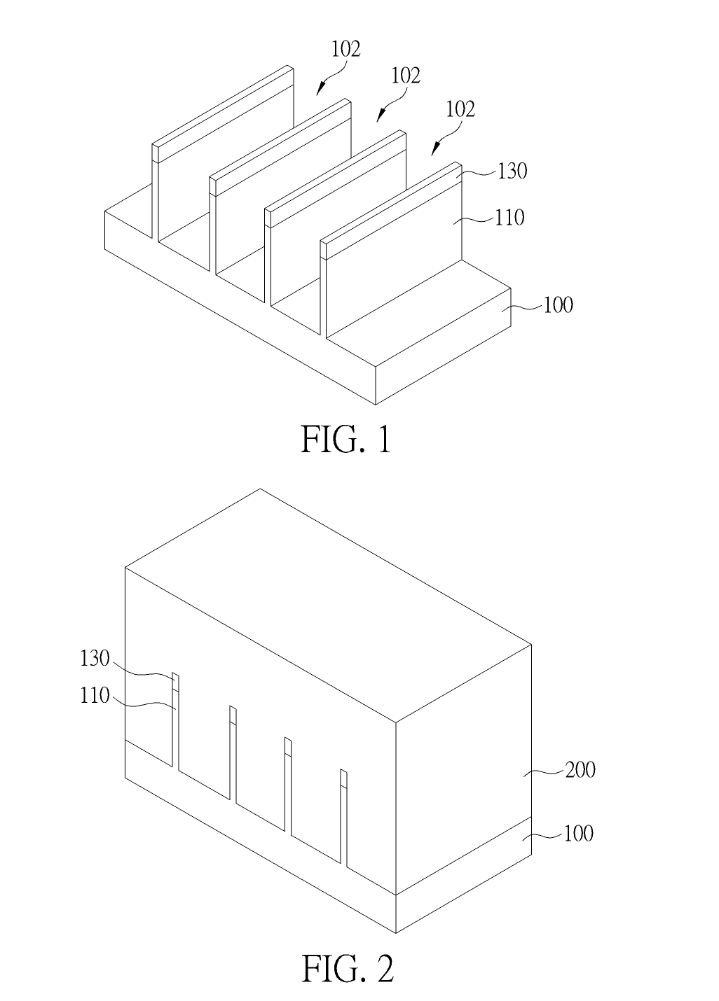

Referring to FIG. 2 and FIG. 10, the process proceeds to step 1006 by depositing a dielectric layer 200 in the trench 102. As shown in FIG. 2, the dielectric layer 200 configured to separate the two adjacent fin-shaped structures 110 is deposited in the trench 102. The dielectric layer 200 functions as an insulating layer or an isolation layer and comprises any suitable insulating materials such as, but not limited to, silicon oxide (SiO₂), silicon nitride (SiN), silicon oxynitride (SiON), fluoride-doped silicate glass, a low-k dielectric material, and a combination thereof. As used herein, the term “low-k dielectric” refers to the material having a dielectric constant, k, smaller than about 3.9, which is the k value of SiO₂. In addition, the dielectric layer 200 may be formed by any suitable process, such as, but not limited to, chemical vapor deposition (CVD), atmospheric pressure chemical vapor deposition (APCVD), low pressure chemical vapor deposition (LPCVD), plasma enhanced chemical vapor deposition (PECVD), metal-organic chemical vapor deposition (MOCVD), flowable chemical vapor deposition (FCVD), physical vapor deposition (PVD), atomic layer deposition (ALD), chemical solution deposition, sputtering, and a combination thereof.

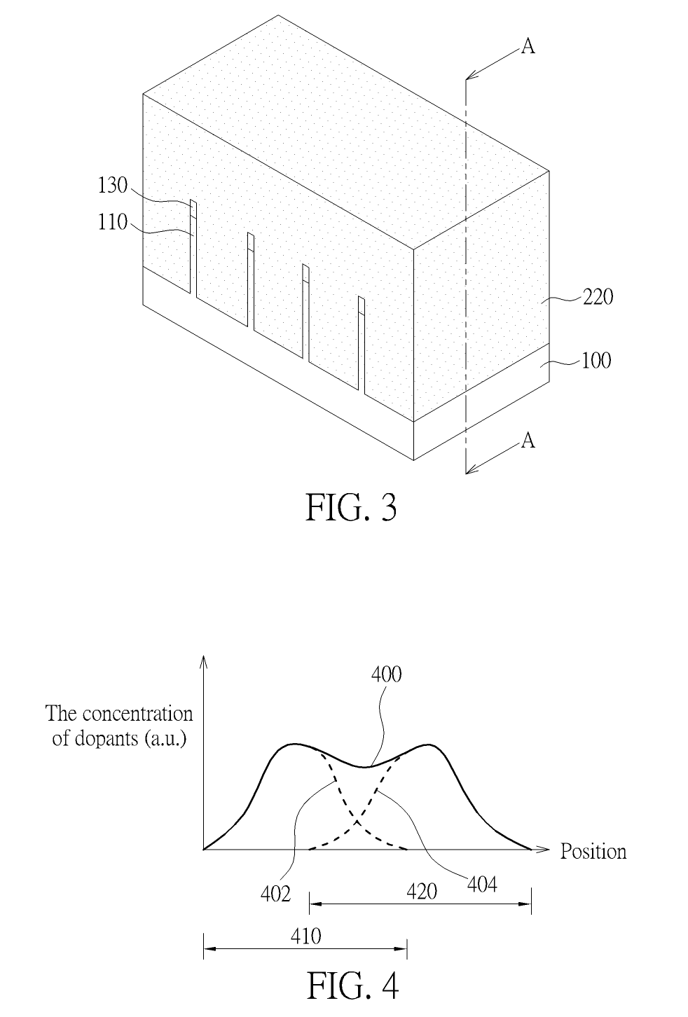

Referring to FIG. 3 and FIG. 10, the process proceeds to steps 1008 and 1010 by doping the dielectric layer 200 with a foreign element. As shown in FIG. 3, a portion of the dielectric layer 200 is doped with a foreign element to form a doped dielectric layer 220. The dielectric layer 200 can be doped by any suitable process such as, but not limited to, ion implantation, plasma doping, laser doping, and a combination thereof. In the embodiment, the dielectric layer 200 is doped by an ion implantation process and the foreign element is preferably helium or neon. In addition, the foreign element doped into the dielectric layer 200 should not enhance an electrical conductivity of the dielectric layer 200. Because increasing of the electrical conductivity of the dielectric layer 200, which is configured to separate different conductive features or active areas, may increase a current leakage and parasitic capacitance that worsen performance of a semiconductor structure. As mentioned above, the foreign element doped into the dielectric layer 200 has better effects to reduce a structural stress between the dielectric layer 200 and the fin-shaped structure 110 during an annealing process, which will be discussed in detail latter.

Furthermore, a position and a thickness of the doped dielectric layer 220 can be controlled by ion implantation parameters such as, but not limited to, kind of ions, implantation time, implantation angle, and implantation energy. By properly setting the parameters, the doped dielectric layer 220 can be formed in a desired position with a desired thickness. In addition, multiple ion implantations of different kinds of foreign elements may be conducted to obtain a desired doped structure of unique characteristics, position, and thickness.

According to this embodiment, a first ion implantation process with implantation energy of 10 keV, 16 keV or 20 keV is conducted to implant foreign element, such as helium or neon, to the dielectric layer 200. Then, a second ion implantation process with implantation energy of 10 keV, 16 keV or 20 keV is conducted to implant foreign element, such as helium or neon, to the dielectric layer 200. Preferably, the first implantation process and the second implantation process are performed at the same temperature and dose, and the implantation energy of the first implantation process is different from the implantation energy of the second implantation process. More preferably, the implantation energy of the first implantation process is less than the implantation energy of the second implantation process. In this way, the foreign elements may be uniformly distributed in the doped dielectric layer 220.

Refer to FIG. 4, which shows the distribution of the foreign elements in the doped dielectric layer taken along line A-A′ of FIG. 3. As shown in FIG. 4, a first doped region 410 and a second doped region 420 are respectively fabricated in the doped dielectric layer 220 during the first ion implantation process and the second ion implantation process. Since the implantation energy of the first ion implantation is preferably slightly less than that of the second ion implantation, the first doped region 410 may be closer to the top surface of the doped dielectric layer 220 compared with the second doped region 420, which causes the first doped region 410 and the second doped region 420 partially overlap each other. Besides, the curves 402 and 404 in FIG. 4 respectively show the distribution of the foreign element in the first doped region 410 and the second doped region 420, and curve 400 shows the overall distribution of the foreign element in the doped dielectric layer 220. It shows that the peak values of the curves 402 and 404 are separated from each other, and the middle of the curve 400 is slightly recessed. Preferably, the peak concentration of the first doped region 410 is above the top surfaces of the fin-shaped structures 110, and the peak concentration of the second doped region 420 is below the top surfaces of the fin-shaped structures 110.

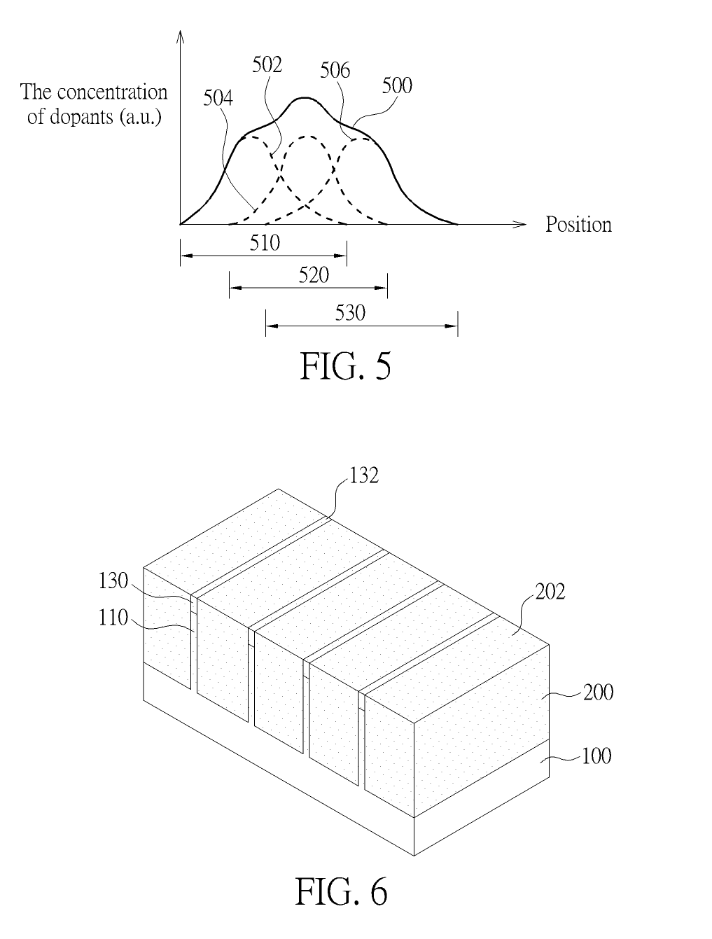

Refer to FIG. 5, which shows the distribution of the foreign elements in the doped dielectric layer taken along line A-A′ of FIG. 3 according to another embodiment of the present invention. The main feature of FIG. 5 is that three ion implantation processes, instead of two ion implantation processes, are conducted to fabricate the doped dielectric layer 220 in FIG. 3. As shown in FIG. 5, a first doped region 510, a second doped region 520, and a third doped region 530 are respectively fabricated in the doped dielectric layer 220 during first, second, and third ion implantation processes. Since the implantation energy of the first to third ion implantation processes are gradually increased, the first doped region 510 may be closer to the top surface of the doped dielectric layer 220 compared with the second and third doped regions 520 and 530, which causes the first doped region 510, the second doped region 520, and the third doped region 530 partially overlap each other. Besides, the curves 502, 504 and 506 in FIG. 5 respectively show the distribution of the foreign element in the first doped region 510, the second doped region 520 and the third doped region 530, and curve 500 shows the overall distribution of the foreign element in the doped dielectric layer 220. It shows that the peak values of the curves 502, 504 and 506 are separated from one another, and the middle of the curve 500 is protruding from the adjacent segments.

Then, the process proceeds to step 1012 by performing an annealing process. In some embodiments, the annealing process is performed at 900° C.˜1100° C. It is understood that the annealing process is aimed to release structural stress of the dielectric layer 200 and expel impurities from the dielectric layer 200. That is to say, the former is relocating position of atoms to compensate or eliminate defects in material, while the latter is removing undesired elements by diffusing them out of material. In particular, several structural defects are generated during depositing the dielectric layer 200, which need to be eliminated before following manufacturing process. Generally, during the annealing of the dielectric layer 200, the shrinkage of the dielectric layer 200 will cause a structural stress on the adjacent structure (i.e. the fin-shaped structure 110) so that the fin-shaped structure 110 may be bending or even cracking. However, according to the disclosure, since the doped dielectric layer 220 have a coefficient of thermal expansion (CTE) closer to the fin-shaped structure 110, the defects of fin-shaped structure 110 such as fin bending or cracking may be avoided during the annealing process.

It should be noted that, in some embodiment, the annealing process and the ion implantation process are performed at the same time. In other embodiments, the annealing process may comprise multiple annealing processes with/without steam or various gases. In other embodiments, the annealing process and the aforementioned ion implantation process may be performed at the same time. In some embodiments, additional annealing process may be performed after the planarization process afterward.

Then, referring to FIG. 6, a planarization process is performed to remove the doped dielectric layer 220 higher than the top surface of the hard mask 130. It should be noted that the planarization process may be stopped when the top surface of the hard mask 130 is exposed.

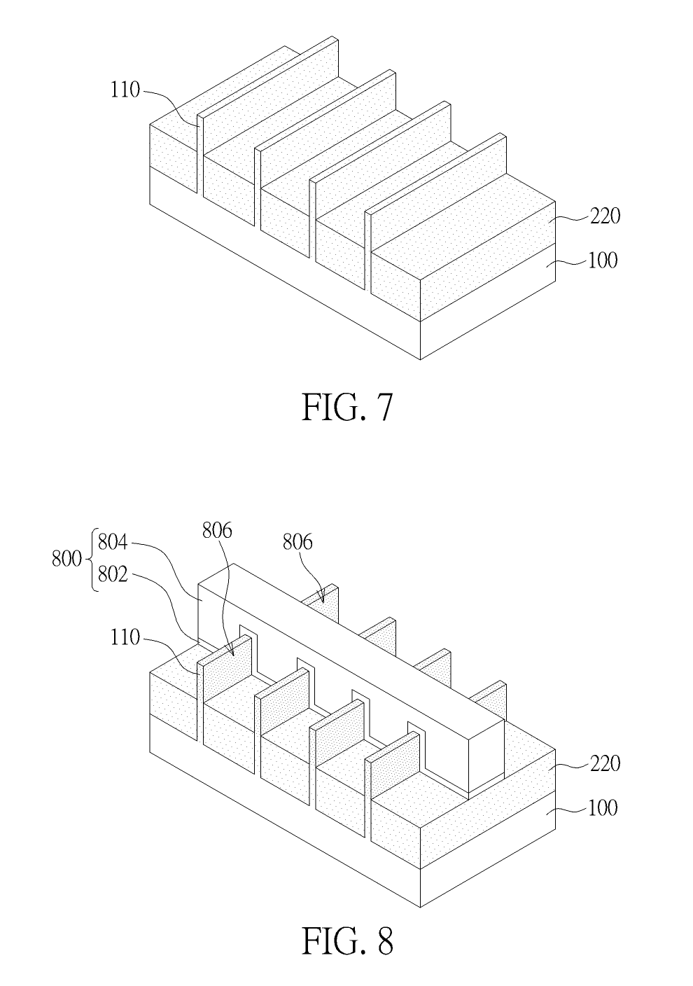

As shown in FIG. 7, in step 1014, an etch process is conducted to remove the doped dielectric layer 220 until upper portions of fin-shaped structures 110 are exposed. It should be noted that there are still certain amount of foreign element in the fin-shaped structures 110 and the doped dielectric layer 220 when the etch process is completed. Preferably, the concentration of the foreign element in the doped dielectric layer 220 is gradually reduced from a position near the top surface of the doped dielectric layer 220 to a position away from the top surface of the doped dielectric layer 220, but not limited thereto.

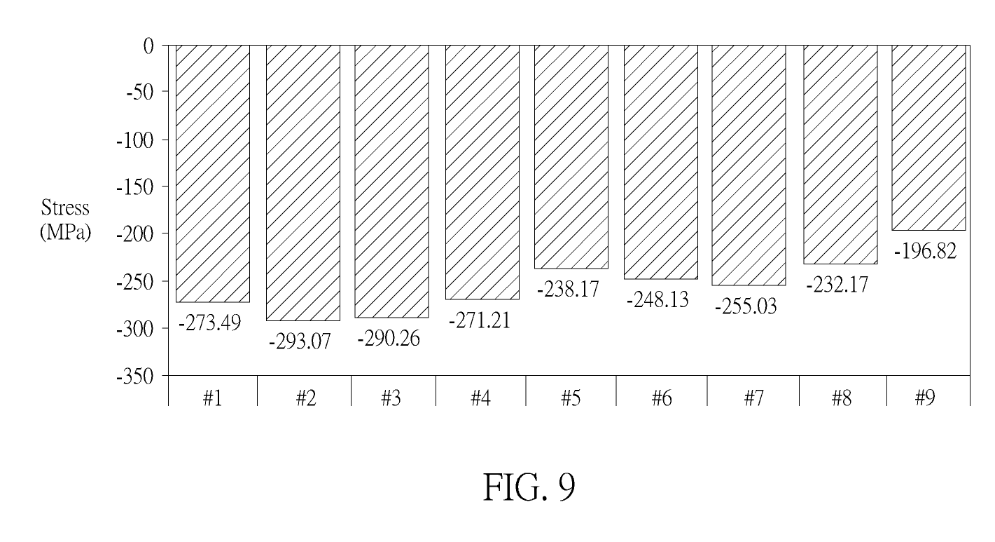

Referring to FIG. 8, a gate structure 800 including a gate dielectric 802 and a gate electrode 804 is then fabricated on the fin-shaped structures 110 and the doped dielectric layer 220. The gate dielectric 802 may wrap around and follows the profile of the fin-shaped structure 110, while the gate electrode 804 is formed on the gate dielectric 802 without being physically connected to the fin-shaped structure 110. The gate dielectric 802 may comprise LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), or other suitable materials. While the gate electrode may comprise a conductive material, such as a metal (e.g., tantalum, titanium, molybdenum, tungsten, platinum, aluminum, hafnium, ruthenium), a metal silicide (e.g., titanium silicide, cobalt silicide, nickel silicide, tantalum silicide), a metal nitride (e.g., titanium nitride, tantalum nitride), doped poly-crystalline silicon, other conductive materials, or a combination thereof. In some embodiments, the gate dielectric layer and the gate electrode are formed by deposition, such as chemical vapor deposition (CVD).

Then, referring to FIG. 8, an ion implantation process may be conducted to implant foreign elements into the fin-shaped structures 110 exposed from the gate structure 800 so as to form doped regions 806 with increased electrical conductivity. The doped regions 806 may be source/drain regions or lightly drain doped (LDD) regions at two sides of the gate structure 800. For a n-type FinFET, the doped regions 806 may include n-type dopants, such as phosphorus (P), arsenic (As), antimony (Sb), bismuth (Bi), selenium (Se), tellurium (Te), and a combination thereof. For the p-type FinFET, the doped regions may include p-type dopants, such as boron (B), boron difluoride (BF₂), and a combination thereof.

Referring to FIG. 9, which shows the compressive stress exerted to fin-shaped structures from a neighboring dielectric layer. In FIG. 9, various treatment conditions respectively corresponding to no. 1 to no. 9 are applied and are summarized in Table 1 below. It should be noted that the data shown in Table 1 and FIG. 9 is for demonstration purpose only and should not be used to restrict the present invention.

TABLE 1

| | first ion implantation | | | | second ion implantation | | | | |
|---|---|---|---|---|---|---|---|---|---|
| | | | energy | dose | | | energy | dose | stress |
| No. | atom | temp. | (keV) | (ion/cm²) | atom | temp. | (keV) | (ion/cm²) | (Mpa) |
| 1 | He | 500 | 10 | 8E15 | | | | | −273.49 |
| 2 | He | 500 | 16 | 8E15 | | | | | −293.07 |
| 3 | He | 500 | 10 | 8E15 | He | 500 | 16 | 8E15 | −290.26 |
| 4 | He | 500 | 10 | 1.6E16 | | | | | −271.21 |
| 5 | He | 200 | 10 | 1E16 | | | | | −238.17 |
| 6 | He | R.T. | 10 | 1E16 | | | | | −248.13 |
| 7 | He | R.T. | 10 | 8E15 | He | R.T. | 16 | 8E15 | −255.03 |
| 8 | | 500 | | | | | | | −232.17 |
| 9 | | | | | | | | | −196.82 |

As shown in Table 1, when the stress is more negative, the compressive stress between fin-shaped structures and the neighboring dielectric layer is more significant. Therefore, by increasing the compressive stress between fin-shaped structures and the neighboring dielectric layer, the drawbacks, such as fin bending and cracking, can be overcome successfully. Furthermore, the compressive stress applied to the fin-shaped structures also increases along with the increase in the temperature of the ion implantations. For example, as shown in Table 1, the compressive stress for the cases where the ion implantation is conducted at 500° C. is generally more intense than the compressive stress for the cases where the ion implantation is conducted at the temperature lower than 500° C., i.e. 25° C. (R.T.) and 200° C.

Those skilled in the art will readily observe that numerous modifications and alterations of the device and method may be made while retaining the teachings of the invention. Accordingly, the above disclosure should be construed as limited only by the metes and bounds of the appended claims.

1: A semiconductor structure, comprising:
a substrate;
a plurality of fin-shaped structures disposed on the substrate;
an isolation layer disposed between the fin-shaped structures;
a first doped region disposed in an upper portion of the isolation layer, wherein the first doped region is doped with helium or neon; and
a second doped region disposed in an lower portion of the isolation layer, wherein the second doped region is doped with helium or neon, and portions of the first doped region overlap portions of the second doped region, and a peak concentration of the first doped region is above top surfaces of the fin-shaped structures, and a peak concentration of the second doped region is below the top surfaces of the fin-shaped structures.

2: The semiconductor structure of claim 1, wherein a top surface of the isolation layer is lower than top surfaces of the fin-shaped structures.

3: The semiconductor structure of claim 1, further comprising another doped region in an upper portion of each of the fin-shaped structures, wherein the doped regions in the fin-shaped structures are doped with helium or neon.

4: The semiconductor structure of claim 1, wherein a bottom surface of the isolation layer is in direct contact with a top surface of the substrate.

5: The semiconductor structure of claim 1, wherein there is a compressive stress induced between the fin-shaped structures and the doped region.

6: The semiconductor structure of claim 5, wherein the compressive stress is applied on the fin-shaped structures.

7: The semiconductor structure of claim 1, wherein a concentration of the doped region is gradually reduced from a position near a top surface of the isolation layer to a position away from the top surface of the isolation layer.

8: A method for fabricating a semiconductor structure, comprising:
providing a substrate;
forming a plurality of fin-shaped structures on the substrate;
forming an isolation layer to fill up a space between the fin-shaped structures;
performing a first ion implantation process to implant an element to the isolation layer, wherein the first ion implantation process has a first ion implantation energy;
performing a second ion implantation process to implant another element to the isolation layer, wherein the second ion implantation process has a second ion implantation energy different from the first ion implantation energy, and a first doped region and a second doped region are respectively formed in the isolation layer during the first ion implantation process and the second ion implantation process, and portions of the first doped region overlap portions of the second doped region, and a peak concentration of the first doped region is above top surfaces of the fin-shaped structures, and a peak concentration of the second doped region is below the top surfaces of the fin-shaped structures; and
annealing the isolation layer after performing the first and the second ion implantation processes.

9: The method of claim 8, wherein the elements implanted to the isolation layer during the first and the second ion implantation processes are helium or neon.

10-12. (canceled)

13: The method of claim 8, wherein the first ion implantation process and the second ion implantation process are performed at the same temperature and dose.

14: The method of claim 8, wherein the first ion implantation energy or the second ion implantation energy is 10 keV, 16 keV, or 20 keV.

15: The method of claim 8, further comprising planarizing the isolation layer after the step of annealing the isolation layer.

16: The method of claim 8, further comprising, after the step of annealing the isolation layer, etching the isolation layer until a top surface of the isolation layer is lower than top surfaces of the fin-shaped structures.

17: The method of claim 8, wherein there is a compressive stress induced between the fin-shaped structures and the isolation layer during the step of annealing the isolation layer.

18: The method of claim 17, wherein the compressive stress is applied on the fin-shaped structures.
